(19) United States
(12) Patent Application Publication
(10) Pub. No.: US 2025/0013149 A1
(43) Pub. Date: Jan. 9, 2025

(54) ADDITIVE FOR 193 NM DRY PHOTORESIST AND PREPARATION METHOD FOR AND APPLICATION OF ADDITIVE

(71) Applicants: SHANGHAI SINYANG SEMICONDUCTOR MATERIALS CO., LTD., Shanghai (CN); CHINA ADVANCED LITHOGRAPHIC MATERIAL TECHNOLOGY CO. LTD., Shanghai (CN)

(72) Inventors: Shunong FANG, Shanghai (CN); Su WANG, Shanghai (CN); Zhiyue GENG, Shanghai (CN); Zhongyue CUI, Shanghai (CN)

(21) Appl. No.: 18/709,039

(22) PCT Filed: Dec. 31, 2021
(86) PCT No.: PCT/CN2021/143502

§ 371 Date: May 10, 2024

(30) Foreign Application Priority Data
Nov. 23, 2021 (CN) 202111395632.9

(51) Int. Cl. G03F 7/004

(52) U.S. Cl. CPC G03F 7/0045; G03F 7/0048

(57) ABSTRACT

An additive for 193 nm dry photoresist and a preparation method for and application of the additive. The structure of the additive is as shown in formula I, the weight-average molecular weight is 1000-3000, and the ratio of the weight-average molecular weight to the number-average molecular weight is 1-5. By using the additive, photoresist can form a photoresist film micropattern having excellent sensitivity and high resolution.

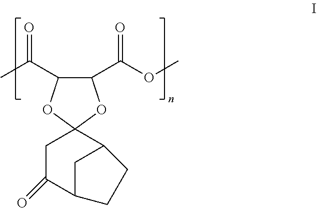

### SPECIFICATION

The application claims the priority of Chinese patent application No. 2021113956329 filed on Nov. 23, 2021, the content of which is incorporated herein by reference in its entirety.

### TECHNICAL FIELD

The present disclosure relates to an additive for 193 nm dry photoresist, and a preparation method therefor and a use thereof.

### BACKGROUND

In the ArF dry photolithography method using an ArF excimer laser as the light source, the space between the projection lens and the wafer substrate is filled with water. According to this method, even when a lens with a numerical aperture (NA) of 1.0 or more is used, a pattern can be formed by using the refractive index of water at 193 nm, and this method is commonly referred to as immersion lithography. However, due to the photoresist film being in direct contact with water, the photoresist patterns may deform or collapse as a result of swelling, or various defects such as bubbles and watermarks may occur. Therefore, there is an urgent need to develop photoresist resins or additives that can improve this situation.

In the microelectronics industry and other industries involving microstructure manufacturing (for example, micromachines, magnetoresistive heads, etc.), there has always been a desire to reduce the size of structural components. In the microelectronics industry, there is a desire to reduce the size of microelectronic devices and/or to provide a greater number of circuits for a given chip size. The capability to manufacture smaller devices is limited by the ability of lithography techniques to reliably resolve smaller features and gaps. The properties of the lens make that the capability to achieve finer resolution is to some extent limited by the wavelength of the light (or other radiation) used to form the lithographic patterns. Consequently, the application of shorter wavelengths in lithography processes has always been an ongoing trend. As the integration and speed of Large Scale Integration (LSI) have increased in recent years, there is a need for accurate micro-patterning of photoresists. ArF light sources (193 nm) or KrF light sources (248 nm) have been widely used as the exposure light sources for forming resist patterns.

Although some photoresist compositions designed for 193 nm radiation have been developed, they generally do not fully demonstrate the true advantages of shorter wavelength imaging resolution due to lacking performance in one or more of the aforementioned areas. Therefore, there is an urgent need to develop photoresist compositions that can be applied to shorter wavelength radiation imaging (for example, 193 nm ultraviolet radiation) and that possess good developability.

### CONTENT OF THE PRESENT INVENTION

To overcome the limitations of using short-wavelength radiation imaging in LSI as found in the prior art, the present disclosure provides an additive for 193 nm dry photoresist, and a preparation method therefor and a use thereof. The additive of the present disclosure is used in photoresists, enabling them to be applied in shorter-wavelength radiation imaging and to possess good developability.

The present disclosure primarily addresses the aforementioned technical problems through the following technical means.

The present disclosure provides an additive of formula I; the weight-average molecular weight of the additive is 1000 to 3000; the ratio of the weight-average molecular weight to the number-average molecular weight of the additive is 1 to 5.

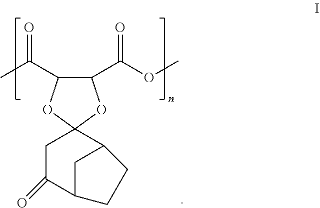

In one embodiment, the weight-average molecular weight of the additive is preferably 1500 to 2500, more preferably 1988.

In one embodiment, the ratio of the weight-average molecular weight to the number-average molecular weight of the additive is preferably 1 to 2, more preferably 1.2.

In one embodiment, the additive is preferably obtained from the following preparation method; the preparation method for the additive preferably comprises the following steps:

S1: in an organic solvent, compound B1 is reacted with dimethyl L-tartrate and p-toluenesulfonic acid through an acetal reaction to obtain compound C1 (bicyclo[3.2.1]octane-2,4-dione-dimethyl L-tartrate); the compound B1 is

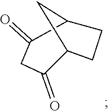

S2: in a solvent, under the action of a base, the compound Cl is subjected to ester hydrolysis reaction to obtain compound DI (bicyclo[3.2.1]octane-2,4-dione-L-tartaric acid);

S3: in an organic solvent, the compound DI is reacted with 4-dimethylaminopyridine through a polymerization reaction to obtain the additive of formula I.

In S1, the organic solvent can be one conventional in the field, preferably an aromatic solvent, such as toluene.

In S1, the molar ratio of the compound B1 to the dimethyl L-tartrate can be one conventional in the field, preferably 1:(1 to 1.5), such as 1:1.

In S1, the molar ratio of the compound B1 to the p-toluenesulfonic acid can be one conventional in the field, preferably 1:(0.02 to 0.04), such as 1:0.029.

In S1, the post-treatment steps for the acetal reaction can be those conventional in the field, preferably operations comprising washing, drying, filtration, and solvent removal. The solvent for the washing can be one conventional in the field, preferably washing with sodium bicarbonate aqueous solution, water, and brine in sequence. The drying is preferably magnesium sulfate drying.

In S1, the duration of the acetal reaction is based on the complete reaction of the reactants, preferably 26 hours to 60 hours, such as 48 hours.

In S1, the temperature of the acetal reaction is preferably the reflux temperature of the solvent at normal temperature and pressure, such as 105 to 115° C.

In S2, the solvent can be one conventional in the field, preferably a ketone solvent, such as N-methylpyrrolidone.

In S2, the base can be one conventional in the field, preferably an inorganic base, such as potassium hydroxide and/or sodium hydroxide, preferably potassium hydroxide.

In S2, the molar volume ratio of the compound Cl to the solvent can be one conventional in the field, preferably 0.1 to 0.7 mol/L, such as 0.33 mol/L.

In S2, the base is preferably used in the form of an aqueous solution. The mass ratio of the base to water is preferably 0.1:1 to 0.6:1, such as 0.3:1.

In S2, after the ester hydrolysis reaction is finished, post-treatment steps can further be included. The post-treatment steps can be those conventional in the field, preferably comprising neutralization and purification operations. The purification step preferably adopts column chromatography, more preferably, ethyl acetate is used as the eluent in the column chromatography.

In S2, the duration of the ester hydrolysis reaction is subject to the fact that the reaction no longer proceeds, preferably 3 hours to 15 hours, such as 6 hours.

In S2, the temperature of the ester hydrolysis reaction is preferably the reflux temperature of the solvent at normal temperature and pressure, such as 190 to 210° C.

In S3, the organic solvent can be one conventional for such reactions in the field, preferably an anhydride solvent, such as acetic anhydride.

In S3, the molar ratio of the 4-dimethylaminopyridine to the compound DI can be one conventional in the field, preferably 1: (900 to 1500), such as 1:1000.

In S3, the molar ratio of the organic solvent to the compound DI can be one conventional in the field, preferably 3:1 to 7:1, such as 5:1.

In S3, the duration of the polymerization reaction is subject to the fact that the reaction no longer proceeds, preferably 3 hours to 20 hours, such as 6 to 16 hours.

In S3, the temperature of the polymerization reaction can be one conventional in the field, preferably 100 to 200° C., such as 130° C. to 190° C.

In S3, the polymerization reaction is carried out in two steps, the first step is to react at 100 to 140° C. for 6 to 8 hours, and the second step is to raise the temperature to 160 to 200° C. and react for 10 to 12 hours; the polymerization reaction is carried out in two steps, preferably, the first step is to react at 130° C. for 6 hours, and the second step is to raise the temperature to 190° C. and react for 10 hours.

In S3, the polymerization reaction may further comprise post-treatment steps; the post-treatment steps can be those conventional in the field, preferably comprising the operations of dissolution and purification.

The present disclosure further provides a preparation method for the additive, and the preparation method for the additive is as described above.

The present disclosure further provides a photoresist comprising the following raw materials: the additive of formula I, a resin of formula (L), a photoacid generator, and a solvent;

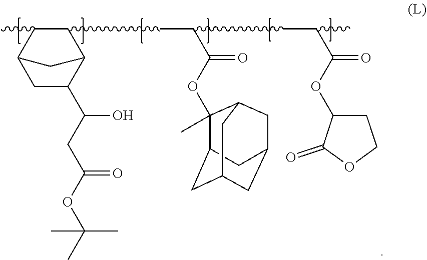

In the photoresist, the amount of the photoacid generator one conventional in the field, wherein, in parts by weight, can be the photoacid generator is preferably 2 to 10 parts by weight, such as 4 parts by weight.

In the photoresist, the photoacid generator can be one conventional in the field,

preferably a sulfonium salt, such as

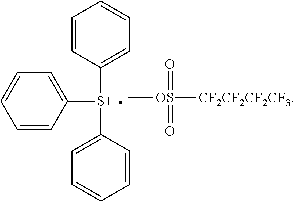

In the photoresist, the weight-average molecular weight of the resin of formula (L) can be one conventional in the field, preferably 8000 to 9000, such as 8500.

In the photoresist, the amount of the resin of formula (L) can be one conventional in the field, wherein, in parts by weight, the resin of formula (L) is preferably 20 to 120 parts by weight, such as 100 parts by weight.

In the photoresist, the amount of the additive of formula I can be one conventional in the field, wherein, in parts by weight, the additive of formula I is preferably 0.1 to 1 parts by weight, such as 0.5 parts by weight.

In the photoresist, the amount of the solvent can be one conventional in the field, wherein, in parts by weight, the solvent is preferably 500 to 2000 parts by weight, such as 1000 parts by weight.

In the photoresist, the solvent can be one conventional in the field, preferably an ester solvent, such as propylene glycol methyl ether acetate.

The photoresist preferably comprises the following raw materials in parts by weight: 4 parts of the photoacid generator, 100 parts of the resin of formula (L), 0.5 parts of the additive of formula I, and 1000 parts of the solvent.

Preferably, the photoresist consists of the following raw materials: the additive of formula I, the resin of formula (L), the photoacid generator, and the solvent.

In the photoresist, the resin of resin: formula (L) is preferably prepared by the following method, and the preparation method for the resin of formula (L) comprises the following steps: in 300 parts by weight of an organic solvent, under the action of 4 parts by weight of an initiator, 100 parts by weight of an unsaturated ester is carried out an polymerization reaction.

After the polymerization reaction, post-treatment steps may further be comprised; the post-treatment steps can be those conventional in the field, preferably comprising precipitation and drying.

In the photoresist, the unsaturated ester can be one conventional in the field, preferably

one or more of tert-butyl 3-bicyclo[2.2.1]hept-5-en-2-yl-3-hydroxypropionate, 1-methyladamantyl acrylate, and y-butyrolactone acrylate.

In the photoresist, the preparation method for the resin of formula (L) preferably comprises the following steps: mixing tert-butyl 3-bicyclo[2.2.1]hept-5-en-2-yl-3-hydroxypropionate, 1-methyladamantyl acrylate, and y-butyrolactone acrylate in a molar ratio of 1:1:1 into a mixture of 100 parts by weight; dissolving the mixture in 300 parts by weight of 1,4-dioxane, and adding 4 parts by weight of azobisisobutyronitrile as an initiator; reacting at 65° C. for 16 hours, followed by precipitation in n-hexane, removal of the precipitate, and vacuum drying.

The present disclosure further provides a preparation method for the photoresist, wherein the preparation method preferably comprises the following steps: in the solvent, mixing the resin of formula (L), the photoacid generator, and the additive of formula I uniformly.

In the preparation method, the solvent, the resin of formula (L), the photoacid generator, and the additive of formula I are as described above (including the types and amounts of raw materials).

In the preparation method, the mixing method can be one conventional in the field.

In the preparation method, the mixing step is preferably followed by a filtration step, such as filtration using a 0.2 μm filter membrane.

The present disclosure further provides an application of the photoresist as described above in a photolithography processes.

Herein, the photolithography process preferably comprises the following steps: coating the photoresist on a pre-treated substrate, drying (for example, drying at 110° C. for 90 seconds), exposing, and developing (for example, using an aqueous solution of tetramethylammonium hydroxide as the developer solution).

In the present disclosure, the weight-average molecular weight and the molecular weight distribution index can be measured by conventional testing methods in the field, such as Gel Permeation Chromatography (GPC).

Based on common knowledge in the field, the preferred conditions described above can be arbitrarily combined to obtain the preferred embodiments of the present disclosure.

In the present disclosure, “normal temperature” refers to 10 to 40° C., and “normal pressure” refers to 98 kPa to 103 kPa.

The reagents and materials used in the present disclosure are commercially available.

The significant advancement of the present disclosure is that the photoresist containing the additive of formula I can form a photoresist film micropattern having excellent sensitivity and high resolution.

### DETAILED DESCRIPTION OF THE PREFERRED EMBODIMENT

The invention will be further described through the following examples, but it should be noted that the invention is not limited to these examples. Experimental methods not specifically mentioned in the following examples are conducted according to conventional methods and conditions or according to the instructions provided with commercial products.

Unless otherwise specified, all operations described below are performed at normal temperature and under normal pressure.

### Example 1: Preparation of Additive

A mixture of dimethyl L-tartrate (9.18 g, 1 eq, 0.05 mol), compound B1

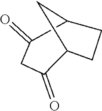

(1 eq, 0.05 mol), and p-toluenesulfonic acid (250 mg) was refluxed in toluene for 48 hours (Dean-Starkwater separator, 0.6 mL of water). The solution was then cooled and washed with bicarbonate aqueous solution (5%, 2×100 mL), water (100 mL), and brine (100 mL). The organic phase was dried (MgSO₄), filtered, and the solvent was removed under reduced pressure to obtain compound C1 (bicyclo[3.2.1]octane-2,4-dione-L-dimethyl tartrate) as an anhydrous liquid with a 91% yield.

2. Ester Hydrolysis Reaction

Compound C1 (0.01 mol) prepared in Example 1 was dissolved in a mixture of NMP (20 mL) and 30% aqueous potassium hydroxide solution (potassium hydroxide (3 g), water (10 g)). The reaction mixture was heated and refluxed for 6 hours, and dilute hydrochloric acid was added to slowly neutralize the mixture. Compound DI (bicyclo[3.2. 1]octane-2,4-dione-L-tartaric acid) was isolated by column chromatography with ethyl acetate as the eluent. The product was a white waxy solid and suitable for direct use in the next step.

3. Polymerization reaction

Compound D1 (0.01 mol) prepared in Example 2 and 4-dimethylaminopyridine (12 mg, 0.01 mmol) were dissolved in acetic anhydride (5 g, 0.05 mol), and the mixture was stirred at 130° C. for 6 hours. The temperature was then raised to 190° C. and the mixture was stirred for about 10 hours, and then the acetic anhydride was removed under reduced pressure. The mixture was cooled to room temperature, and the solid product was dissolved in DMSO. The mixture was purified by precipitation in toluene to obtain polymer Al (the additive of formula

I). GPC analysis showed the molecular weight Mw of 1988 and the Mw/Mn of 1.2.

### Example 2: Preparation of Resin

Tert-butyl 3-bicyclo[2.2.1]hept-5-en-2-yl-3-hydroxypropionate (hereinafter referred to as BHP), 1-methyladamantyl acrylate, and γ-butyrolactone acrylate was added in a molar ratio of 1:1:1. Relative to 100 parts by weight of the total amount of reactive monomers, 300 parts by weight of 1,4-dioxane were added as the solvent in the polymerization reaction, and relative to 100 parts by mole of the total amount of reactive monomers, 4 parts by mole of azobisisobutyronitrile were added as the initiator, and the mixture was reacted at 65° C. for 16 hours. After the reaction, the reaction solution was precipitated with n-hexane, and the precipitate was removed, and the residue was dried under vacuum. As a result, the resin of formula (L) was obtained, with a weight-average molecular weight of approximately 8500 g/mol.

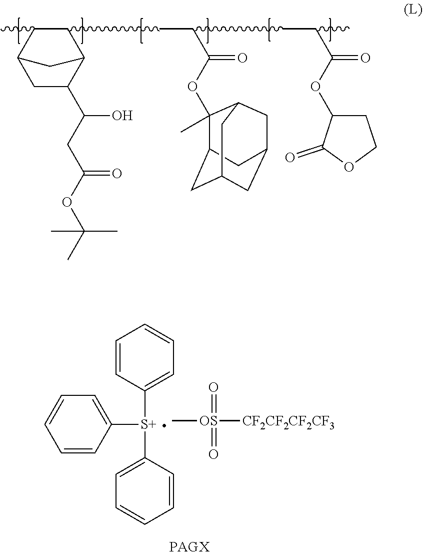

### Photoresist Preparation Example

100 parts by weight of the resin of formula (L), 4 parts by weight of the photoacid generator PAGX, and 0.5 parts by weight of the additive of formula I were dissolved in 1000 parts by weight of propylene glycol methyl ether acetate. The solution was then filtered through a 0.2 μm membrane filter. Thus the photoresist was prepared.

### Comparative Example 1

Compound C2 was prepared by replacing Compound B1 in step 1 of Example 1 with Compound B2, and polymer A2 was prepared by ester hydrolysis and polymerization with reference to steps 2 and 3 of Example 1 in turn. GPC analysis revealed a molecular weight Mw of 2100 and an Mw/Mn of 1.2.

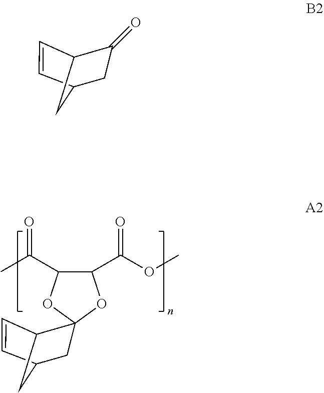

### Comparative Example 2

Compound C3 was prepared by replacing Compound B1 in step 1 of Example 1 with compound B3, and polymer A3 was prepared by ester hydrolysis and polymerization with reference to steps 2 and 3 of Example 1 in turn. GPC analysis revealed a molecular weight Mw of 1840 and an Mw/Mn of 1.0.

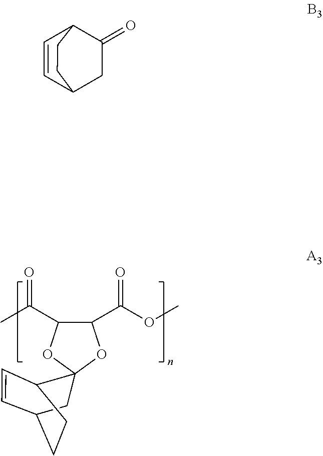

### Effect Example

A bottom anti-reflection coating (BARC, AR40A-900, Rohm and Haas Electronic Materials Co., Ltd.) with a thickness of 90nm was formed on a silicon substrate, and the photoresist composition prepared as above was coated on the substrate with BARC. The substrate was baked at 110° C. for 60 seconds to form a photoresist film with a thickness of 120 nm.

The thickness change of each photoresist film before and after development was measured by developing the silicon substrate with the photoresist film using a 2.38 wt % aqueous solution of tetramethylammonium hydroxide (TMAH) and measuring the thickness of the photoresist film.

Exposure was carried out using an ArF scanner ASML-1400 at 110° C. for 60 seconds. PEB was performed, and patterns were formed by developing with a 2.38 wt % TMAH developer for 60 seconds.

The silicon substrate was cut to evaluate sensitivity. The sensitivity corresponds to the exposure dose used to form a 65nm line-and-space (L/S) pattern with a ratio of a line-width to line-space of 1:1.

TABLE 1

| | | Thickness after | |
|---|---|---|---|
| | | Development | |
| Photoresist Film | Additive | (nm) | Sensitivity (mJ/cm²) |
| Photoresist Preparation Example 1 | Polymer A1 | 4 | 46 |
| Photoresist Preparation Example 2 | Polymer A2 | 4 | No pattern formation |
| Photoresist Preparation Example 3 | Polymer A3 | 4 | No pattern formation |

Referring to Table 1, after photolithography, the photoresist film formed using the photoresist composition containing the photoresist additive prepared in the Examples has excellent sensitivity compared with the photoresist film formed using the photoresist composition containing the photoresist additive prepared in the Comparative Examples, and no pattern is formed on the photoresist film formed using those in the Comparative Examples.

1. An additive of formula I, wherein the additive has a weight-average molecular weight of 1000 to 3000; the ratio of the weight-average molecular weight to the number-average molecular weight of the additive is 1 to 5;

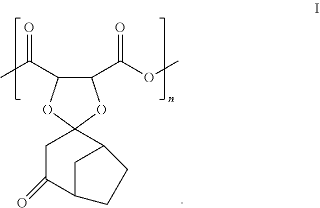

2. The additive according to claim 1, wherein the additive has a weight-average molecular weight of 1500 to 2500;
or, the ratio of the weight-average molecular weight to the number-average molecular weight of the additive is 1 to 2.

3. The additive according to claim 1, wherein the additive is obtained from the following preparation method, and the preparation method comprises the following steps:
S1: in an organic solvent, compound B1 is reacted with dimethyl L-tartrate and p-toluenesulfonic acid through an acetal reaction to obtain compound C1; the compound B1 is 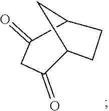
the compound Cl is bicyclo [3.2.1] octane-2,4-dione-dimethyl L-tartrate;
S2: in a solvent, under the action of a base, the compound Cl is subjected to ester hydrolysis reaction to obtain compound D1; the compound DI is bicyclo [3.2.1] octane-2,4-dione-L-tartaric acid;
S3: in an organic solvent, the compound D1 is reacted with 4-dimethylaminopyridine through a polymerization reaction to obtain the additive of formula I.

4. The additive according to claim 3, wherein, in S1, the organic solvent is an aromatic solvent;
or, in S1, the molar ratio of the compound B1 to the dimethyl L-tartrate is 1: (1 to 1.5);
or, in S1, the molar ratio of the compound B1 to the p-toluenesulfonic acid is 1: (0.02 to 0.04);
or, in S1, the duration of the acetal reaction is 26 hours to 60 hours;
or, in S1, the temperature of the acetal reaction is the reflux temperature of the solvent at normal temperature and pressure;
or, in S2, the solvent is a ketone solvent;
or, in S2, the base is an inorganic base;
or, in S2, the base is used in the form of an aqueous solution, and the mass ratio of the base to water is 0.1:1 to 0.6:1;
or, in S2, the molar volume ratio of the compound C1 to the solvent is 0.1 to 0.7 mol/L;
or, in S2, the duration of the ester hydrolysis reaction is 3 hours to 15 hours;
or, in S2, the temperature of the ester hydrolysis reaction is the reflux temperature of the solvent at normal temperature and pressure;
or, in S3, the organic solvent is an anhydride solvent;
or, in S3, the molar ratio of 4-dimethylaminopyridine to the compound DI is 1: (900 to 1500);
or, in S3, the molar ratio of the organic solvent to the compound DI is 3:1 to 7:1;
or, in S3, the duration of the polymerization reaction is 3 hours to 20 hours;
or, in S3, the temperature of the polymerization reaction is 100 to 200° C.;
or, in S3, the polymerization reaction is carried out in two steps, the first step is to react at 100 to 140° C. for 6 to 8 hours, and the second step is to raise the temperature to 160 to 200° C. and react for 10 to 12 hours.

5. The additive according to claim 4, wherein, in S1, the organic solvent is toluene;
or, in S1, the molar ratio of the compound B1 to dimethyl L-tartrate is 1:1;
or, in S1, the molar ratio of the compound B1 to p-toluenesulfonic acid is 1:0.029;
or, in S1, the duration of the acetal reaction is 48 hours;
or, in S2, the solvent is N-methylpyrrolidone;
or, in S2, the base is potassium hydroxide or sodium hydroxide;
or, in S2, the base is used in the form of an aqueous solution, and the mass ratio of the base to water is 0.3:1;
or, in S2, the molar volume ratio of the compound C1 to the solvent is 0.33 mol/L;
or, in S2, the duration of the ester hydrolysis reaction is 6 hours;
or, in S3, the organic solvent is acetic anhydride;
or, in S3, the molar ratio of the 4-dimethylaminopyridine to the compound D1 is 1:1000;
or, in S3, the molar ratio of the organic solvent to the compound DI is 5:1;
or, in S3, the duration of the polymerization reaction is 6 to 16 hours;
or, in S3, the temperature of the polymerization reaction is 130 to 190° C.;
or, in S3, the polymerization reaction is carried out in two steps, the first step is to react at 130° C. for 6 hours, and the second step is to raise the temperature to 190° C. and react for 10 hours.

6. The additive according to claim 5, wherein, in S2, the base is potassium hydroxide.

7. A preparation method for the additive, wherein, in the preparation method, the operations and conditions are the same as the operations and conditions of the preparation method for the additive according to claim 3.

8. A photoresist, wherein the photoresist comprises the following raw materials: the additive according to claim 1, a resin of formula (L), a photoacid generator, and a solvent;

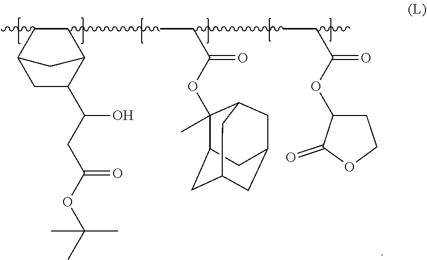

9. The photoresist according to claim 8, wherein the resin of formula (L) is obtained by the following steps: mixing tert-butyl 3-bicyclo [2.2.1] hept-5-en-2-yl-3-hydroxypropionate, 1-methyladamantyl acrylate, and y-butyrolactone acrylate in a molar ratio of 1:1:1 into a mixture of 100 parts by weight; dissolving the mixture in 300 parts by weight of 1,4-dioxane, and adding 4 parts by weight of azobisisobutyronitrile as an initiator; reacting at 65° C. for 16 hours, followed by precipitation in n-hexane, removal of the precipitate, and vacuum drying;
or, in parts by weight, the amount of the additive is 0.1 to 1 parts by weight;
or, in parts by weight, the weight-average molecular weight of the resin of formula (L) is 8000 to 9000;
or, in parts by weight, the amount of the resin of formula (L) is 20 to 120 parts by weight;
or, in parts by weight, the amount of the photoacid generator is 2 to 10 parts by weight;
or, the photoacid generator is 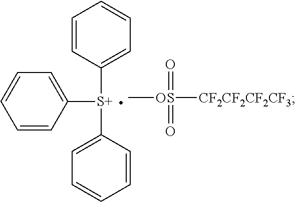
or, in parts by weight, the amount of the solvent is 500 to 2000 parts by weight;
or, the solvent is an ester solvent.

10. The photoresist according to claim 9, wherein the photoresist comprises the following raw materials in parts by weight: 4 parts of the photoacid generator, 100 parts of the resin of formula (L), 0.5 parts of the additive, and 1000 parts of the solvent.

11. A preparation method for the photoresist according to claim 8, wherein the preparation method comprises the following steps: in the solvent, mixing the resin of formula (L), the photoacid generator, and the additive uniformly.

12. (canceled)

13. The additive according to claim 2, wherein the additive has a weight-average molecular weight of 1988;
or, the ratio of the weight-average molecular weight to the number-average molecular weight of the additive is 1.2.

14. The photoresist according to claim 9, wherein, in parts by weight, the amount of the additive is 0.5 parts by weight;
or, in parts by weight, the weight-average molecular weight of the resin of formula (L) is 8500;
or, in parts by weight, the amount of the resin of formula (L) is 100 parts by weight;
or, in parts by weight, the amount of the photoacid generator is 4 parts by weight;
or, in parts by weight, the amount of the solvent is 1000 parts by weight;
or, the solvent is propylene glycol methyl ether acetate.

15. The photoresist according to claim 10, wherein the photoresist consists of the following components: the additive, the resin of formula (L), the photoacid generator, and the solvent.
